(19) United States
(12) Patent Application Publication
(10) Pub. No.: US 2005/0201059 A1
(43) Pub. Date: Sep. 15, 2005

(54) Heat dissipation device with heat pipes

(76) Inventors: Kai-Hung Lin, Chung Ho City (TW); Hsiang-Jung Chin, Kaohsiung City (TW); Heng-Li Chou, San Chung City (TW); Wen-Liang Hwang, Hsin Chuang City (TW)

Correspondence Address: RABIN & BERDO, P.C.;Suite 500, 1101 14th Street, Washington, DC, 20005, US

(21) Appl. No.: 10/990,445

(22) Filed: Nov. 18, 2004

(30) Foreign Application Priority Data
Mar. 10, 2004 (TW) 93106394

(51) Int. Cl. H05K 7/20

(52) U.S. Cl. 361/700

(57) ABSTRACT

A heat dissipation device with heat pipes is described. The heat dissipation device includes at least one U-shaped heat pipe, a plurality of heat fins, and a heat sink base. A middle portion of the U-shaped heat pipe is coupled to the heat sink base to receive thermal energy and transmit the same to two arm portions of the U-shaped heat pipe so as to improve the heat dissipation efficiency. A fixing plate is further utilized to fix the U-shaped heat pipe onto the heat sink base. The fixing plate further absorbs the thermal energy and the thermal energy is transmitted from the middle portion of the U-shaped heat pipe to the two arm portions of the U-shaped heat pipe and then to the heat fins. Therefore, the heat dissipation device can increase the heat dissipation efficiency while reducing the space it occupies in an electrical device.

### RELATED APPLICATIONS

The present application is based on, and claims priority from, Taiwan Application Serial Number 93106394, filed on Mar. 10, 2004, the disclosure of which is hereby incorporated by reference herein in its entirety.

### FIELD OF THE INVENTION

The present invention relates to a heat dissipation device, and more particularly, to a heat dissipation device with U-shaped heat pipes.

### BACKGROUND OF THE INVENTION

Information technology and the computer industry are highly developed now. Because computers have powerful calculation capability and can deal with a great amount of digital data, computers are popularly used in myriad applications. With progresses in semiconductor manufacturing processes and semiconductor functions, electronic circuit layout of semiconductors has become more and more complicated and sophisticated.

For example, an electronic circuit layout of a new generation central processing unit (CPU) is more complicated than an old one because the new generation CPU has to provide more powerful functions for users and application software. The new generation CPU provides powerful functionality and performance but also generates new problems in use. One serious problem is that the new generation CPU, with its more complicated circuitry, has higher power consumption and thus has a higher working temperature. The higher working temperature can cause instability in an operating system of the computer. In general, a lower working temperature makes a computer more stable. That is to say, if the computer working temperature can be kept lower, the performance thereof is higher. On the contrary, if the computer working temperature is too high, the performance and stability will decrease and the operating system may even crash in some extreme situations.

Conventionally, a heat dissipation device is mounted on a new generation CPU having high power consumption to directly exhaust the heat generated by the CPU. The fan of the heat dissipation device blows on the heat fins of the heat dissipation device mounted on the CPU to exhaust the heat out of the computer. For effective exhausting, a conventional heat dissipation device utilizes heat pipes to transmit the heat to the heat fins, and the heat is then removed from the computer.

As the heat generated by the newer generation CPUs increases, computers need a larger heat dissipation device to remove the heat. However, large heat dissipation devices are not suitable for new generation computers, which are constantly decreasing in volume.

### SUMMARY OF THE INVENTION

One objective of the present invention is to utilize a U-shaped heat pipe to increase a heat dissipation efficiency of a heat dissipation device for reducing a temperature of a CPU surface.

Another objective of the present invention is to utilize a U-shaped heat pipe to increase a heat dissipation efficiency of a heat dissipation device so as to reduce the volume of the heat dissipation device.

The present invention provides a heat dissipation device to remove heat generated by a heat source, particularly to remove heat generated by an integrated circuit, for example, a central processing unit of a computer. The heat dissipation device includes a base, at least one U-shaped heat pipe, and a plurality of heat fins. The U-shaped heat pipe is coupled to the base for enhancing the heat dissipation efficiency of the heat dissipation device. The base further includes at least one trench to couple to at least one U-shaped heat pipe. The fixing plate is made of a high thermal conductivity metal, for example, copper. The heat generated by the heat source is absorbed by the base and the fixing plate, transmitted to a middle portion of the U-shaped heat pipe and subsequently transmitted to the heat fins via two arm portions of the U-shaped heat pipe so as to remove the heat from the heat dissipation device.

The base is made of a high thermal conductivity metal, for example, aluminum. The fixing plate can be coupled to the base by a plurality of fixing devices, for example, screws. The U-shaped heat pipe can be fixed on the base by welding or gluing.

The U-shaped heat pipe increases the contact area between the base and the U-shaped heat pipe so that the heat generated by the heat source can be easily transmitted to the heat fins via the U-shaped heat pipe and exhausted. The heat dissipation device further utilizes the fixing plate made of copper to increase the heat dissipation efficiency. Hence, the heat dissipation device according to the present invention can effectively increase heat dissipation efficiency while reducing the volume occupied in an electrical device.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic view of a preferred embodiment of a heat dissipation device with U-shaped heat pipes according to the present invention;

FIG. 2A is a schematic side view of the preferred embodiment of FIG. 1;

FIG. 2B is a schematic rear view of the preferred embodiment of FIG. 1; and

FIG. 2C is a schematic bottom view of the preferred embodiment of FIG. 1.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

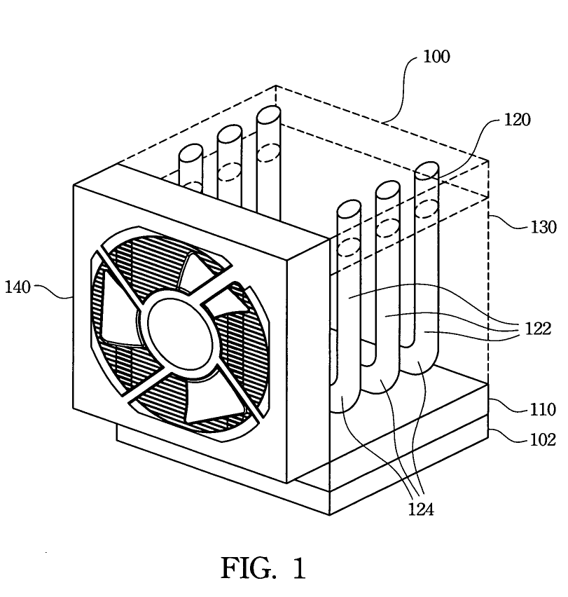

FIG. 1 is a schematic view of a preferred embodiment of a heat dissipation device with U-shaped heat pipes according to the present invention. The heat dissipation device 100 has a base 110, U-shaped heat pipes 120 mounted on the base 110 and passing through heat fins 130 which coupled to the U-shaped heat pipes 120. An undersurface of the base 110 couples to a central processing unit (CPU) 102 or any other heat source to absorb heat generated therefrom and transmit the heat to a middle portion 124 of the U-shaped heat pipe 120. Subsequently, the heat is transmitted to two arm portions 122 of the U-shaped heat pipe 120 and then to the heat fins 130 disposed parallel to the base 110. A fan 140 disposed beside the heat dissipation device 100 blows air on the heat fins 130 to remove the heat out of the heat dissipation device 100.

The heat dissipation device 100 utilizes at least one U-shaped heat pipe 120 to transmit the heat. The U-shaped heat pipe 120 is made of a high thermal conductivity material, for example, aluminum or copper. The middle portion 124 of the U-shaped heat pipe 120 is utilized to absorb more heat from the base 110, compared with a conventional I-shaped heat pipe, and the heat is subsequently transmitted to both arm portions 122 of the U-shaped heat pipe 120. Therefore, the heat can quickly and uniformly be transmitted to the heat fins 130. Accordingly, the heat dissipation efficiency of the heat dissipation device 100 is improved. Moreover, each of the heat fins 130 can uniformly and adequately dissipate the heat so as to effectively reduce the size of the heat fins 130.

As compared with a conventional heat pipe of a heat dissipation device, the middle portion 124 of the U-shaped heat pipe 120 contacts the base 110 over a larger area so as to absorb more heat from the base 110. Therefore, the U-shaped heat pipe 120 can sufficiently transmit the heat to the heat fins 130, enhancing the heat dissipation efficiency of the heat dissipation device 100 while reducing the volume thereof.

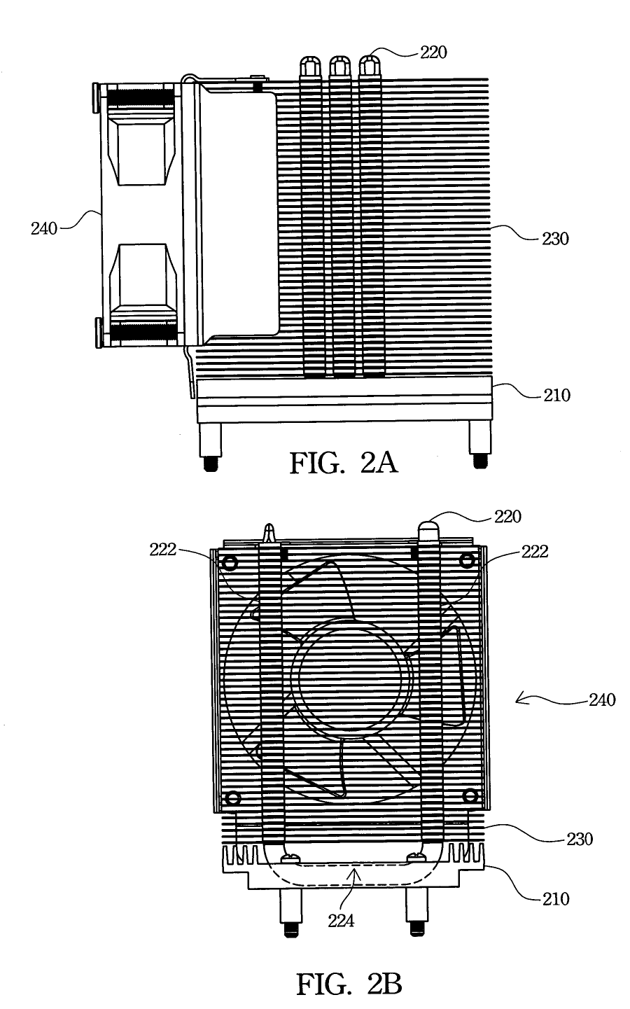

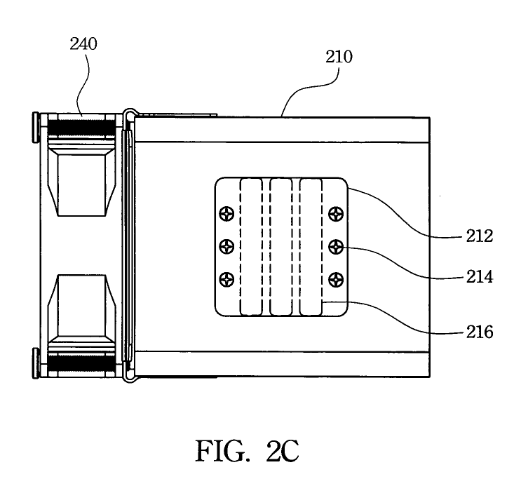

FIG. 2A is a schematic side view of the preferred embodiment of the heat dissipation device with U-shaped heat pipes according to the present invention as illustrated in FIG. 1. FIG. 2B is a schematic rear view thereof and FIG. 2C is a schematic bottom view thereof. The middle portion 224 of the U-shaped heat pipe 220 couples to the base 210, and the two arm portions 222 of the U-shaped heat pipe 220 couple to the heat fins 230. Therefore, the U-shaped heat pipe 220 can effectively transmit the heat from a source via the base 210 to the heat fins 230 and subsequently out of the heat dissipation device with airflow generated by a fan 240. The U-shaped heat pipe 220 is preferably perpendicular to the airflow direction of the fan 240 and parallel to the surfaces of the heat fins. Accordingly, the two arm portions 222 of the U-shaped heat pipe 220 can be simultaneously cooled by the airflow generated by the fan 240.

However, the U-shaped heat pipe 220 of the heat dissipation device according to the present invention is not limited to be perpendicularly arranged to the airflow of the fan 240. The U-shaped heat pipe 220 and the airflow can be arranged in a predetermined angle and the two arm portions 222 of the U-shaped heat pipe 220 still can transmit the heat to the heat fins 230. The heat fins 230 can be made of a high thermal conductivity material, preferably a sheet metal such as an aluminum sheet metal or a copper sheet metal, with openings for heat pipes to pass through. The U-shaped heat pipe 220 and the heat fins 230 can be coupled by welding or gluing to fix the heat fins 230 to the U-shaped heat pipe 220 and enhance thermal conductivity therebetween. The foregoing openings for fitting the exterior shape of the U-shaped heat pipe 220 are not limited to round openings. The openings can be square, elliptic or any other shape to fit a corresponding U-shaped heat pipe with square, elliptic or any other exterior shape.

The U-shaped heat pipe 220 can simultaneously transmit the heat absorbed by the middle portion 224 to the two arm portions 222, and the middle portion 224 of the U-shaped heat pipe 220 can increase the contact area for transmitting heat from the base 210. The base 210 can further form trenches 216 to couple to the middle portion 224 of the U-shaped heat pipe 220. The middle portion 224 of U-shaped heat pipe 220 can further be fixed onto the base 210 by welding or gluing to further increase the thermal conductivity thereof. Thus, the heat dissipation device according to the present invention can effectively increase the heat dissipation efficiency thereof while reducing the volume occupied by the heat dissipation device.

Referring to FIG. 2C, a fixing plate 212 fixes the middle portion 224 of the U-shaped heat pipe 220 onto the base 210 via fixing devices 214 or any other fixing process such as welding or gluing. The fixing plate 212 further contacts the heat source to absorb the heat generated by the heat source and increase the heat dissipation efficiency of the heat dissipation device. The heat is subsequently transmitted to the middle portion 224 of the U-shaped heat pipe 220 and then to the heat fins 230 via the two arm portions 222 of the U-shaped heat pipe 220. The base 210 and the fixing plate 212 are made of a high thermal conductivity material like aluminum or copper to effectively enhance the heat dissipation efficiency of the heat dissipation device according to the present invention.

Because the middle portion 224 of the U-shaped heat pipe 220 is transversely coupled to the base 210 by the fixing plate 212 and/or the trench 216, thus increasing the contact area therebetween, the U-shaped heat pipe 220 can absorb more heat generated by the heat source and transmit the heat to the heat fins 230 coupled onto the two arm portions 222 of the U-shaped heat pipe 220.

Hence, the heat dissipation efficiency of the heat dissipation device according to the present invention can be increased, and each of the heat fins can be supplied with uniform heat to dissipate the heat uniformly. Even the heat fins coupled to an end of an arm portion of the heat pipe are supplied with heat due to the high heat dissipation efficiency of the U-shaped heat pipe, creating more effective heat dissipation. Thus, the heat dissipation device according to the present invention provides an increased heat dissipation capability on a controlled volume thereof.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest possible interpretation so as to encompass all such modifications and similar structures.

1. A heat dissipation device, comprising:
a base coupled to a heat source;
at least one U-shaped heat pipe having two arm portions and a middle portion, the middle portion being coupled to the base;
a plurality of heat fins coupled to the U-shaped heat pipe, wherein the base absorbs heat generated by a heat source, and the heat is transmitted to the heat fins via the U-shaped heat pipe to remove the heat from the heat dissipation device; and
a fan coupled to the heat fins to provide airflow to remove the heat generated from the heat source.

2. The heat dissipation device of claim 1, wherein the base further comprises a fixing plate to fix the middle portion of the U-shaped heat pipe onto the base.

3. The heat dissipation device of claim 2, wherein the fixing plate absorbs the heat generated by the heat source to transmit the heat to the heat fins via the middle portion and the arm portions of the U-shaped heat pipe.

4. The heat dissipation device of claim 2, wherein the fixing plate, the U-shaped heat pipe and the base are made of a high thermal conductivity metal.

5. The heat dissipation device of claim 4, wherein the fixing plate is made of copper.

6. The heat dissipation device of claim 4, wherein the base is made of aluminum.

7. The heat dissipation device of claim 1, wherein the base further comprises at least one trench to couple to at least one U-shaped heat pipe.

8. The heat dissipation device of claim 1, wherein the two arm portions of the U-shaped heat pipe pass through the heat fins.

9. A heat dissipation device, comprising:
a base with a trench;
a plurality of heat fins arranged above and parallel to the base; and
a U-shaped heat pipe passing through the heat fins and coupled to the base, wherein the U-shaped heat pipe further comprises two arm portions and a middle portion and the middle portion is coupled to the base, wherein the base absorbs heat generated by a heat source and the heat is transmitted to the heat fins via the middle portion and the arm portions of the U-shaped heat pipe to remove the heat from the heat dissipation device.

10. The heat dissipation device of claim 9, wherein the U-shaped heat pipe and the base are made of a high thermal conductivity metal.

11. The heat dissipation device of claim 10, wherein the base further comprises a fixing plate made of copper to fix the middle portion of the U-shaped heat pipe onto the base.

12. The heat dissipation device of claim 10, wherein the base is made of aluminum.

13. The heat dissipation device of claim 9, wherein the heat dissipation device further comprises a fan configured beside the heat fins to provide airflow to remove the heat from the heat fins of the heat dissipation device.

14. A heat dissipation device, comprising:
a base with at least one trench;
at least one U-shaped heat pipe coupled to the base, wherein each of the U-shaped heat pipes further comprises two arm portions and a middle portion and the middle portion is coupled to the base;
a fixing plate coupling the middle portions of the U-shaped heat pipes to the trenches of the base; and
a plurality of heat fins coupled to the arm portions of the U-shaped heat pipes, wherein the base absorbs heat generated by a heat source and the heat is transmitted to the heat fins via the middle portion and the arm portions of the U-shaped heat pipe to remove the heat from the heat dissipation device.

15. The heat dissipation device of claim 14, wherein the heat dissipation device further comprises a fan configured beside the heat fins to provide airflow to remove the heat from the heat fins of the heat dissipation device.

16. The heat dissipation device of claim 15, wherein the U-shaped heat pipe is perpendicular to the airflow of the fan.

17. The heat dissipation device of claim 15, wherein the U-shaped heat pipe and the airflow of the fan form an angle.

18. The heat dissipation device of claim 14, wherein the fixing plate is made of copper, the base is made of aluminum, and a plurality of fixing devices couple the copper fixing plate to the aluminum base.

19. The heat dissipation device of claim 18, wherein the fixing devices comprise screws.

20. The heat dissipation device of claim 18, wherein the U-shaped heat pipe is fixed on the aluminum base by welding or gluing.

21. The heat dissipation device of claim 14, wherein the fixing plate, the U-shaped heat pipe and the base are made of a high thermal conductivity metal.
